(19) United States
(12) Patent Application Publication
(10) Pub. No.: US 2025/0118561 A1
(43) Pub. Date: Apr. 10, 2025

(54) WORKPIECE PROCESSING METHOD

(71) Applicant: DISCO CORPORATION, Tokyo (JP)

(72) Inventors: Younsuk KIM, Tokyo (JP); Byeongdeck JANG, Tokyo (JP); Yuriko SATO, Tokyo (JP); Yoshiteru NISHIDA, Tokyo (JP); Susumu YOKOO, Tokyo (JP); Kenji OKAZAKI, Tokyo (JP)

(21) Appl. No.: 18/894,401

(22) Filed: Sep. 24, 2024

(30) Foreign Application Priority Data
Oct. 5, 2023 (JP) 2023-173656

(51) Int. Cl. H01L 21/268; H01L 21/683

(52) U.S. Cl. CPC H01L 21/268; H01L 21/6836

(57) ABSTRACT

A workpiece processing method for a workpiece having a first surface and a second surface on a back side of the first surface includes: forming a water-soluble protective film that covers the first surface of the workpiece; after forming the water-soluble protective film is performed, holding a first surface side of the workpiece with a holding table and exposing a second surface side; after holding the first surface side of the workpiece is performed, processing the workpiece from the second surface side of the workpiece; and after processing the workpiece is performed, cleaning the first surface side of the workpiece to remove the water-soluble protective film.

### CROSS-REFERENCE TO RELATED APPLICATION(S)

The present application claims priority to and incorporates by reference the entire contents of Japanese Patent Application No. 2023-173656 filed in Japan on Oct. 5, 2023.

### BACKGROUND

The present disclosure relates to a workpiece processing method.

In performing laser processing by applying a laser beam to a wafer, the wafer is irradiated with the laser beam from a back surface side in some cases. In order to facilitate handling of the wafer, the back surface of the wafer is fixed onto a tape, and when the wafer is irradiated with the laser beam from the back surface side, the laser beam is emitted to the back surface of the wafer through the tape with a front surface side of the wafer held on a holding table.

In such a case, in order to prevent damage of the front surface of the wafer due to contact with a table holding surface, a porous sheet is mounted on the table holding surface to hold the wafer via the porous sheet (see, e.g., JP 2016-076671 A).

In recent years, a so-called hybrid bonding method have been adopted, in which electrodes of devices obtained by dividing a semiconductor device wafer are directly bonded to each other without using bumps or the like. In the hybrid bonding, a foreign matter(s) present between the devices causes bonding failure, and therefore, no foreign matter adhering to a wafer after processing is required.

However, in a case where the front surface of the wafer on is held on the holding table through the porous sheet, the foreign matter adhering to the porous sheet may adhere to the front surface of the wafer, and improvement is desired.

### SUMMARY

A workpiece processing method for a workpiece according to one aspect of the present disclosure is a processing method for a workpiece having a first surface and a second surface on a back side of the first surface, and includes: forming a water-soluble protective film that covers the first surface of the workpiece; after forming the water-soluble protective film is performed, holding a first surface side of the workpiece with a holding table and exposing a second surface side; after holding the first surface side of the workpiece is performed, processing the workpiece from the second surface side of the workpiece; and after processing the workpiece is performed, cleaning the first surface side of the workpiece to remove the water-soluble protective film.

### BRIEF DESCRIPTION OF THE DRAWINGS

FIG. 1 is a perspective view schematically illustrating a configuration example of a workpiece to be processed by a workpiece processing method according to a first embodiment;

FIG. 2 is a flowchart illustrating a procedure of the workpiece processing method according to the first embodiment;

FIG. 3 is a perspective view illustrating the workpiece after a tape-fixing step of the workpiece processing method illustrated in FIG. 2;

FIG. 4 is a schematic side partial cross-sectional view illustrating a water-soluble protective film forming step of the workpiece processing method illustrated in FIG. 2;

FIG. 5 is a schematic side partial cross-sectional view illustrating a holding step of the workpiece processing method illustrated in FIG. 2;

FIG. 6 is a schematic side partial cross-sectional view illustrating a processing step of the workpiece processing method illustrated in FIG. 2;

FIG. 7 is a schematic side partial cross-sectional view of a dividing device holding the workpiece in a dividing step of the workpiece processing method illustrated in FIG. 2;

FIG. 8 is a schematic side partial cross-sectional view of the workpiece divided into individual chips by the dividing device in the dividing step of the workpiece processing method illustrated in FIG. 2; and

FIG. 9 is a schematic side partial cross-sectional view illustrating a cleaning step of the workpiece processing method illustrated in FIG. 2.

### DETAILED DESCRIPTION

Embodiments according to the present disclosure will be described in detail with reference to the drawings. The present invention is not limited to the contents described in the following embodiments. In addition, constituent elements described below include those that are readily conceivable by those skilled in the art and those that are substantially equivalent. Furthermore, configurations described below can be appropriately combined. Still furthermore, various omissions, substitutions, or modifications of the configurations can be made without departing from the gist of the present invention.

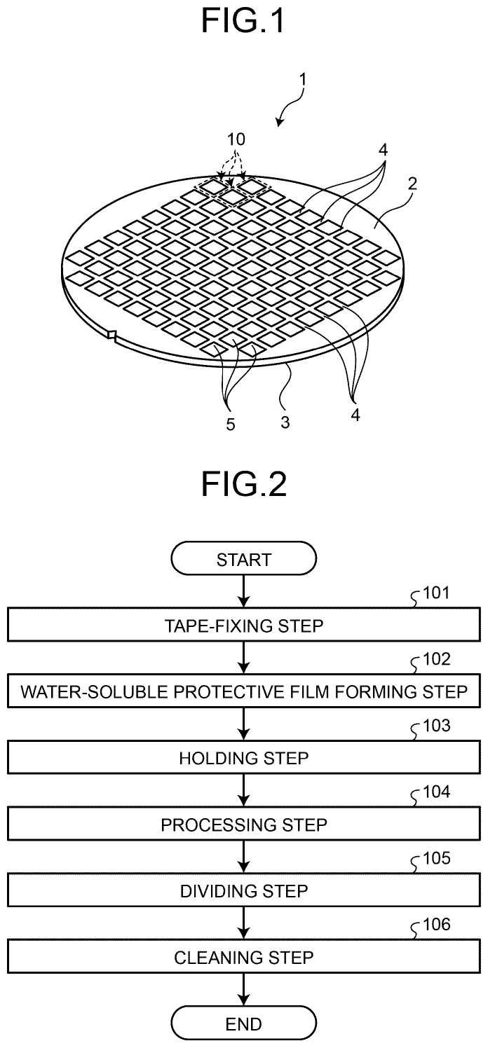

A workpiece processing method according to an embodiment will be described with reference to the drawings. FIG. 1 is a perspective view schematically illustrating a configuration example of a workpiece to be processed by the workpiece processing method according to the first embodiment. FIG. 2 is a flowchart illustrating a procedure of the workpiece processing method according to the first embodiment.

### Workpiece

The workpiece processing method according to the first embodiment is a method of processing the workpiece 1 illustrated in FIG. 1. In the first embodiment, the workpiece 1 to be processed by the workpiece processing method is a wafer such as a disk-shaped semiconductor wafer or an optical device wafer including silicon, sapphire, gallium arsenide, silicon carbide (SiC), or the like as a substrate. As illustrated in FIG. 1, the workpiece 1 includes a substrate having a front surface 2 (corresponding to a first surface) and a back surface 3 (corresponding to a second surface) on a back side of the front surface 2. In the workpiece 1, devices 5 are respectively formed in a plurality of regions defined by a plurality of planned division lines 4 that intersect (orthogonal, in the first embodiment) on the front surface 2 (corresponding to the first surface) of the substrate.

The device 5 is, for example, an integrated circuit such as an integrated circuit (IC) or a large scale integration (LSI), an image sensor such as a charge coupled device (CCD) or a complementary metal oxide semiconductor (CMOS), a micro electro mechanical systems (MEMS), and the like, or various memories (semiconductor storage devices).

In the present invention, the workpiece 1 is not limited to the wafer illustrated in FIG. 1. Furthermore, in the present invention, the device 5 may not be formed on the front surface 2 of the workpiece 1.

The workpiece 1 is divided into individual chips 10 along the planned division lines 4. Each of the chips 10 includes: a part of the substrate; and the device 5.

### Workpiece Processing Method

The workpiece processing method according to the first embodiment is a method of dividing the workpiece 1 illustrated in FIG. 1 into the individual chips 10. As illustrated in FIG. 2, the workpiece processing method according to the first embodiment includes a tape-fixing step 101, a water-soluble protective film forming step 102, a holding step 103, a processing step 104, a dividing step 105, and a cleaning step 106.

### Tape-Fixing Step

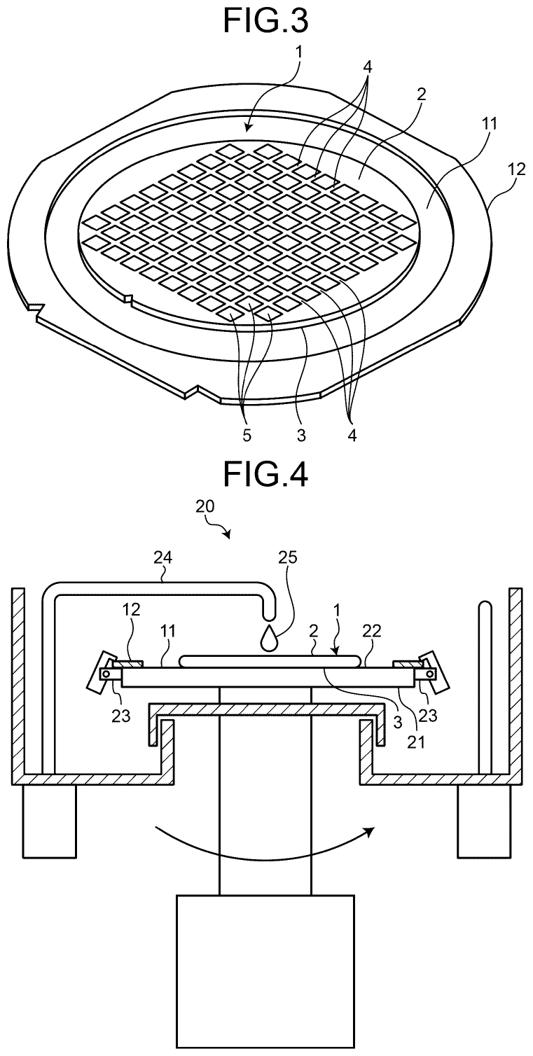

FIG. 3 is a perspective view illustrating the workpiece after the tape-fixing step of the workpiece processing method illustrated in FIG. 2. The tape-fixing step 101 is a step of fixing the back surface 3 side of the workpiece 1 to a tape 11 before or after the water-soluble protective film forming step 102 is performed.

In the first embodiment, in the tape-fixing step 101, the tape 11 formed in a disk shape having a diameter larger than that of the workpiece 1 is bonded to the back surface 3 of the workpiece 1, and an annular frame 12 having an annular shape is bonded to an outer edge portion of the tape 11, thereby supporting the workpiece 1 in an opening portion of the annular frame 12, as illustrated in FIG. 3. In the present invention, the tap-fixing step 101 is performed at least before the holding step 103, and may be performed after the water-soluble protective film forming step 102 is performed.

### Water-Soluble Protective Film Forming Step

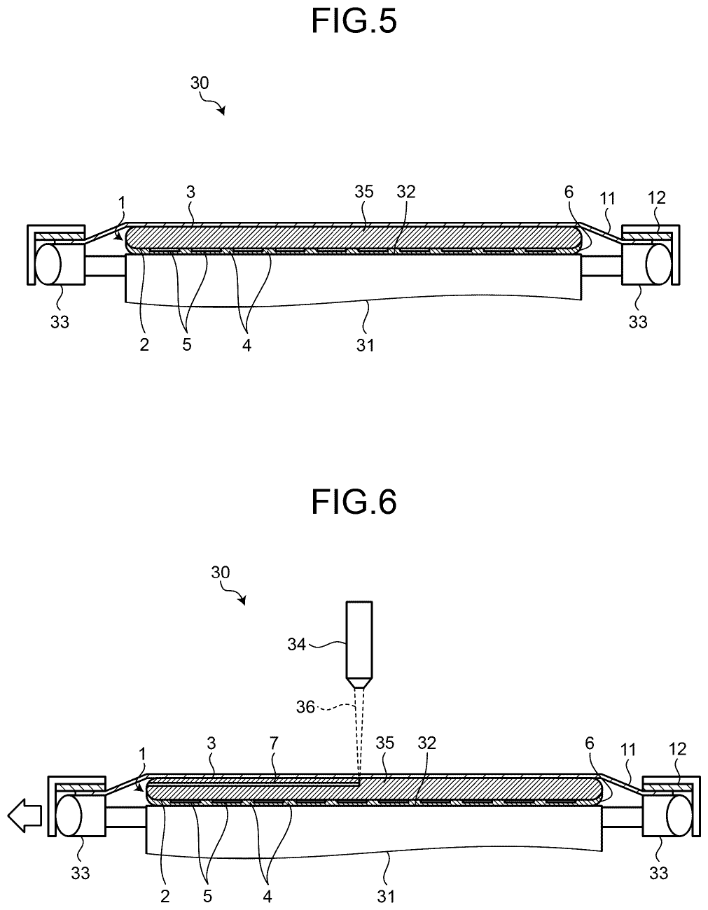

FIG. 4 is a schematic side partial cross-sectional view illustrating the water-soluble protective film forming step of the workpiece processing method illustrated in FIG. 2. The water-soluble protective film forming step 102 is a step of forming a water-soluble protective film 6 (illustrated in FIG. 5) that covers the front surface 2 of the workpiece 1.

In the first embodiment, in the water-soluble protective film forming step 102, the back surface 3 side of the workpiece 1 is placed on a holding surface 22 of a spinner table 21 of a coating device 20 via the tape 11. In the first embodiment, in the water-soluble protective film forming step 102, the coating device 20 holds the back surface 3 side of the workpiece 1 on the holding surface 22 of the spinner table 21 via the tape 11 in a suction manner to clamp the annular frame 12 with a clamp unit 23.

In the first embodiment, in the water-soluble protective film forming step 102, the coating device 20 supplies a coating liquid 25 onto the center of the front surface 2 of the workpiece 1 from a supply nozzle 24 while rotating the spinner table 21 about its rotation axis, as illustrated in FIG. 4. As a result, the coating liquid 25 flows toward the outer periphery of the workpiece 1 owing to a centrifugal force of the rotation of the spinner table 21, and covers the entire front surface 2 of the workpiece 1.

In the first embodiment, the coating liquid 25 is, for example, a water-soluble liquid resin such as polyvinyl alcohol (PVA) or polyvinylpyrrolidone (PVP) (e.g., HogoMax (registered trademark) manufactured by DISCO Corporation).

In the first embodiment, in the water-soluble protective film forming step 102, after retracting the supply nozzle 24 from above the front surface 2 of the workpiece 1, the coating liquid 25 covering the front surface 2 of the workpiece 1 mounted on the spinner table 21 is dried, so that the water-soluble protective film 6 is formed on the front surface 2 of the workpiece 1 to cover the front surface 2.

### Holding Step

FIG. 5 is a schematic side partial cross-sectional view illustrating the holding step of the workpiece processing method illustrated in FIG. 2. The holding step 103 is a step of holding the front surface 2 side of the workpiece 1 on a holding table 31 and exposing the back surface 3 side after the water-soluble protective film forming step 102 is performed.

In the first embodiment, in the holding step 103, the front surface 2 side of the workpiece 1 is placed on a holding surface 32 of the holding table 31 of a laser processing device 30 via the water-soluble protective film 6, and the water-soluble protective film 6 makes contact with the holding surface 32. In the first embodiment, in the holding step 103, as illustrated in FIG. 5, the laser processing device 30 holds the front surface 2 side of the workpiece 1 on the holding surface 32 of the holding table 31 via the water-soluble protective film 6 in a suction manner to clamp the annular frame 12 with a clamp unit 33. In the present invention, in the holding step 103, a porous sheet may or may not be provided between the water-soluble protective film 6 on the front surface 2 of the workpiece 1 and the holding surface 32 of the holding table 31.

### Processing Step

FIG. 6 is a schematic side partial cross-sectional view illustrating the processing step of the workpiece processing method illustrated in FIG. 2. The processing step 104 is a step of processing the workpiece 1 from the back surface 3 side of the workpiece 1 after the holding step 103 is performed.

In the first embodiment, in the processing step 104, the laser processing device 30 performs alignment for positioning the planned division line 4 of the workpiece 1 held on the holding table 31 and a laser application unit 34. In the first embodiment, in the processing step 104, as illustrated in FIG. 6, the laser processing device 30 irradiates, using the laser application unit 34, the workpiece 1 with a pulsed laser beam 36 having a wavelength transmissive to the workpiece 1 along the back surface 3 of the workpiece 1 through the tape 11 in a condition in which a focal point 35 of the laser beam 36 is positioned inside the workpiece 1, while relatively moving the holding table 31 and the laser application unit 34 along the planned division lines 4.

In the first embodiment, in the processing step 104, the laser beam 36 has the wavelength transmissive to the workpiece 1, and therefore, the laser processing device 30 forms a modified layer 7 along the planned division lines 4 inside the workpiece 1, as illustrated in FIG. 6. The modified layer 7 means a region whose physical characteristic such as density, refractive index, mechanical strength, and the like are different from those of the surrounding regions. Examples of the modified layer 7 include a melt-processed region, a crack region, a breakdown region, a refractive index change region, and a region in which these regions are mixed. The modified layer 7 has mechanical strength lower than those of the other portions of the workpiece 1. In this manner, in the first embodiment, in the processing step 104, the laser beam 36 is emitted toward the back surface 3 side of the workpiece 1 through the tape 11.

### Dividing Step

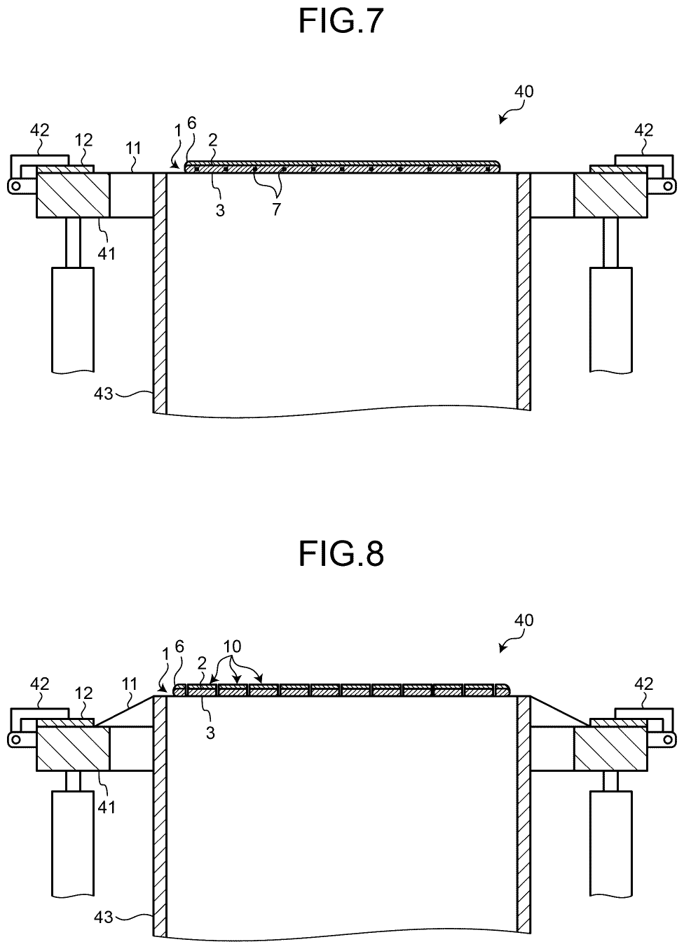

FIG. 7 is a schematic side partial cross-sectional view of a dividing device holding the workpiece in the dividing step of the workpiece processing method illustrated in FIG. 2. FIG. 8 is a schematic side partial cross-sectional view of the workpiece divided into individual chips by the dividing device in the dividing step of the workpiece processing method illustrated in FIG. 2. The dividing step 105 is a step of dividing the workpiece 1 into individual chips 10.

In the first embodiment, in the dividing step 105, the dividing device 40 causes a frame mounting plate 41 to move up and the annular frame 12 supporting the workpiece 1 with a conveyance unit which is not illustrated is placed on an upper surface of the frame mounting plate 41 in a state in which clamping by a clamp mechanism 42 is released. In the first embodiment, in the dividing step 105, the dividing device 40 clamps the annular frame 12 on the frame mounting plate 41 using the clamp mechanism 42, and holds the workpiece 1 via the annular frame 12, as illustrated in FIG. 7.

in the first embodiment, in the dividing step 105, the dividing device 40 causes the frame mounting plate 41 to move down as illustrated in FIG. 8. An upper end of an expansion drum 43 is in contact with the tape 11 between an outer edge of the workpiece 1 and an inner edge of the annular frame 12, presses the tape 11 upward from below, thereby expanding the tape 11 in a plane direction. In the dividing step 105, as a result of expansion of the tape 11, a radial tensile force acts on the tape 11.

When the radial tensile force acts on the tape 11 bonded to the back surface 3 of the workpiece 1 in this manner; since the modified layer 7 is formed along the planned division lines 4, the workpiece 1 is divided into the individual chips 10 along the planned division lines 4 with the modified layer 7 as break starting points. Furthermore, in the workpiece 1, the chips 10 are separated to form intervals between the chips 10. In addition, when the radial tensile force acts on the tape 11, the water-soluble protective film 6 is broken apart for each of the chips 10 along the modified layer 7, that is, along the planned division lines 4.

### Cleaning Step

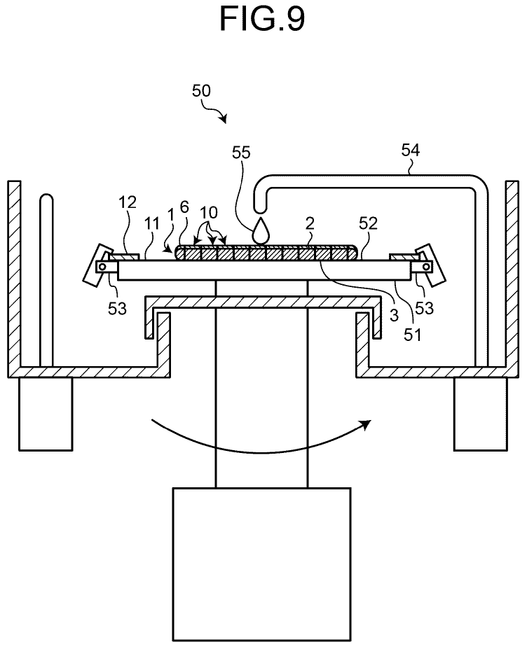

FIG. 9 is a schematic side partial cross-sectional view illustrating the cleaning step of the workpiece processing method illustrated in FIG. 2. The cleaning step 106 is a step of cleaning the front surface 2 side of the workpiece 1 to remove the water-soluble protective film 6, after the processing step 104 is performed.

in the first embodiment, in the cleaning step 106, the back surface 3 side of the workpiece 1 is placed on a holding surface 52 of a spinner table 51 of a cleaning device 50 via the tape 11. In the first embodiment, in the cleaning step 106, the cleaning device 50 holds the back surface 3 side of the workpiece 1 on the holding surface 52 of the spinner table 51 via the tape 11 in a suction manner to clamp the annular frame 12 with a clamp unit 53.

In the first embodiment, in the cleaning step 106, the cleaning device 50 supplies, from a cleaning nozzle 54, cleaning water 55 (in the embodiment, pure water) onto the center of the front surface 2 of the workpiece 1 while rotating the spinner table 51 about its rotation axis, as illustrated in FIG. 9. As a result, the cleaning water 55 flows toward the outer periphery of the workpiece 1 owing to the centrifugal force of the rotation of the spinner table 51, and washes the entire front surface 2 of the workpiece 1 to remove the water-soluble protective film 6.

As described above, in the workpiece processing method according to the first embodiment, the water-soluble protective film 6 is formed on the front surface 2 of the workpiece 1 in the water-soluble protective film forming step 102, the workpiece 1 is held in a state where the water-soluble protective film 6 makes contact with the holding surface 32 of the holding table 31 in the holding step 103, and the workpiece 1 is processed from the back surface 3 side in the processing step 104.

Furthermore, in the workpiece processing method according to the first embodiment, the front surface 2 side of the workpiece 1 is cleaned and the water-soluble protective film 6 is removed in the cleaning step 106 after the processing step 104. This makes it possible to inhibit direct contact of the front surface 2 of the workpiece 1 with the holding surface 32 of the holding table 31 and the porous sheet.

As a consequence, the workpiece processing method according to the first embodiment provides an effect of suppressing adhesion of foreign matter on the front surface 2 of the workpiece 1.

According to the present disclosure, adhesion of the foreign matter to the front surface of the workpiece is suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A workpiece processing method for a workpiece having a first surface and a second surface on a back side of the first surface, the method comprising:
forming a water-soluble protective film that covers the first surface of the workpiece;
after forming the water-soluble protective film is performed, holding a first surface side of the workpiece with a holding table and exposing a second surface side;
after holding the first surface side of the workpiece is performed, processing the workpiece from the second surface side of the workpiece; and
after processing the workpiece is performed, cleaning the first surface side of the workpiece to remove the water-soluble protective film.

2. The workpiece processing method according to claim 1, further comprising
before or after forming the water-soluble protective film is performed, fixing the second surface side of the workpiece to a tape,
wherein, processing the workpiece includes emitting a laser beam toward the second surface side of the workpiece through the tape.
